(19) United States
(12) Patent Application Publication
(10) Pub. No.: US 2019/0371825 A9
(43) Pub. Date: Dec. 5, 2019

(54) STACK STRUCTURE AND PREPARATION METHOD THEREOF

(71) Applicants: BOE TECHNOLOGY GROUP CO., LTD., Beijing, (CN); HEFEI BOE OPTOELECTRONICS TECHNOLOGY CO., LTD., Hefei, Anhui (CN)

(72) Inventors: Miao YUAN, Beijing (CN); Na ZHAO, Beijing (CN)

(21) Appl. No.: 15/772,248

(22) PCT Filed: Sep. 28, 2017
(86) PCT No.: PCT/CN2017/103979

§ 371 Date: Apr. 30, 2018

(30) Foreign Application Priority Data
Mar. 27, 2017 (CN) 201710188507.8

(51) Int. Cl. H01L 27/12; H01L 29/423; H01L 21/768

(52) U.S. Cl. CPC H01L 27/1244; H01L 21/76885; H01L 29/42372; H01L 27/127

(57) ABSTRACT

The disclosure relates to a stack structure and a preparation method thereof. The stack structure a substrate, at least one material layer located on the substrate, a via penetrating through at least one portion of the at least one material layer, wherein the via has a stepped side surface, and another material layer conformally covering the side surface of the via. A ratio of a thickness of the at least one material layer to a thickness of the another material layer is greater than 10.

### CROSS-REFERENCE TO RELATED APPLICATIONS

This patent application is a National Stage Entry of PCT/CN2017/103979 filed on Sep. 28, 2017, which claims the benefit and priority of China Patent Application No. 201710188507.8, filed on Mar. 27, 2017, the disclosures of which are incorporated herein by reference in their entirety as part of the present application.

### BACKGROUND

With the continuous promotion of the flat panel display technology, the technology of Thin Film Transistor (TFT) has also been rapidly developed. The increasing number of mask layers results in that the phenomenon of via in a TFT preparation process is increasingly common. When the depth of a via is too large, in particular for the current organic film via, the depth thereof is dozens of times of the thickness of the conductive layer located above. Such a great thickness difference would easily make the conductive layer have a risk of wire breakage due to the difficulty in climbing when the conductive layer covers the via.

Liquid crystal display includes a thin film transistor (TFT) substrate, a color filter substrate, and a liquid crystal layer therebetween. Color filter substrate is mainly for the purpose of filtering incident light to achieve a color display. After incident color-mixed light passes through red/green/blue materials, light of red/green/blue wavelengths is transmitted, accordingly. However, this type of color display is often affected by dyes and cannot achieve a high color gamut. In addition, since red/green/blue color materials can only transmit light of a specific wavelength, the loss of light intensity is serious.

### BRIEF DESCRIPTION

Embodiments of the present disclosure provide a stack structure and a preparation method thereof.

A first aspect of the present disclosure provides a stack structure including a substrate, at least one material layer located on the substrate, a via penetrating through at least one portion of the at least one material layer, wherein the via has a stepped side surface, and another material layer conformally covering the side surface of the via.

In an embodiment, a ratio of a thickness of the at least one material layer to a thickness of the another material layer is greater than 10.

In an embodiment, the stack structure further includes a thin film transistor, wherein the at least one material layer covers at least the thin film transistor, the via exposes a source/drain electrode or a gate electrode of the thin film transistor, and the another material layer includes a conductive layer.

In an embodiment, the at least one material layer includes an organic film layer.

In an embodiment, a thickness of the organic film layer is about 20,000 Angstroms, and a thickness of the conductive layer is smaller than about 1,000 Angstroms.

In an embodiment, the stack structure further includes a passivation layer located on the conductive layer, and a further conductive layer located on the passivation layer.

A second aspect of the present disclosure provides a method of preparing a stack structure, the method including forming at least one material layer on a substrate, forming a via penetrating through at least one portion of the at least one material layer in the at least one material layer, wherein the via has a stepped side surface, and conformally forming another material layer on the at least one material layer to cover the side surface of the via.

In an embodiment, a ratio of a thickness of the at least one material layer to a thickness of the another material layer is greater than 10.

In an embodiment, a method of forming the via includes forming a first via having a first width penetrating through the at least one material layer, wherein a depth of the first via is smaller than the thickness of the at least one material layer, and forming, at the bottom of the first via, a second via having a second width penetrating through the at least one material layer, wherein the first width is greater than the second width, and a side surface of the second via is not continuous with a side surface of the first via.

In an embodiment, a method of forming the via includes forming a third via having a third width penetrating through the at least one material layer, and forming, at the top of the third via, a fourth via having a fourth width penetrating through the at least one material layer, wherein the third width is smaller than the fourth width, and a side surface of the third via is not continuous with a side surface of the fourth via.

In an embodiment, the at least one material layer includes an organic film layer.

In an embodiment, a method of forming the via includes forming the via having the stepped side surface by one patterning process using a halftone mask, wherein the halftone mask includes a fully-transparent region, a semi-transparent region located on both sides of the fully-transparent region and an opaque region located on both sides of the semi-transparent region.

In an embodiment, the method further includes forming a thin film transistor on the substrate prior to forming the at least one material layer, wherein the via exposes a source/drain electrode or a gate electrode of the thin film transistor, and the another material layer includes a conductive layer, and the method further includes forming a passivation layer on the another material layer; and forming a further conductive layer on the passivation layer.

In an embodiment, a thickness of the organic film layer is about 20,000 Angstroms, and a thickness of the conductive layer is smaller than about 1,000 Angstroms.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

FIG. 1 is a cross-section view schematically illustrating a stack structure according to an embodiment of the present disclosure;

FIG. 2 is a cross-section view schematically illustrating a stack structure including a thin film transistor according to an embodiment of the present disclosure;

FIG. 3 is a schematic diagram schematically illustrating forming at least one material layer of a method of preparing a stack structure according to an embodiment of the present disclosure;

FIG. 4 is a schematic diagram schematically illustrating forming a via of a method of preparing a stack structure according to an embodiment of the present disclosure;

FIG. 5 is a schematic diagram schematically illustrating forming another material layer of a method of preparing a stack structure according to an embodiment of the present disclosure;

FIG. 6 is a schematic diagram schematically illustrating forming a first via of a method of preparing a stack structure according to an embodiment of the present disclosure;

FIG. 7 is a schematic diagram schematically illustrating forming a second via of a method of preparing a stack structure according to an embodiment of the present disclosure;

FIG. 8 is a schematic diagram schematically illustrating forming a third via of a method of preparing a stack structure according to an embodiment of the present disclosure;

FIG. 9 is a schematic diagram schematically illustrating forming a fourth via of a method of preparing a stack structure according to an embodiment of the present disclosure;

FIG. 10 is a schematic diagram schematically illustrating forming a via of a method of preparing a stack structure according to an embodiment of the present disclosure; and

FIG. 11 is a schematic diagram schematically illustrating forming a stack structure including a thin film transistor of a method of preparing a stack structure according to an embodiment of the present disclosure.

Corresponding reference numerals indicate corresponding parts or features throughout the several views of the drawings.

### DETAILED DESCRIPTION

As used herein and in the appended claims, the singular form of a word includes the plural, and vice versa, unless the context clearly dictates otherwise. Thus, the references “a”, “an”, and “the” are generally inclusive of the plurals of the respective terms. Similarly, the words “comprise”, “comprises”, and “comprising” are to be interpreted inclusively rather than exclusively. Likewise, the terms “include”, “including” and “or” should all be construed to be inclusive, unless such a construction is clearly prohibited from the context. Where used herein the term “examples,” particularly when followed by a listing of terms is merely exemplary and illustrative, and should not be deemed to be exclusive or comprehensive.

In addition, in the drawings, the thickness and area of each layer are exaggerated for clarity. It should be understood that when a layer, a region, or a component is referred to as being “on” another part, it is meant that it is directly on the another part, or there may be other components in between. In contrast, when a certain component is referred to as being “directly” on another component, it is meant that no other component lies in between.

Further to be noted, when the elements and the embodiments thereof of the present application are introduced, the articles “a/an”, “one”, “the” and “said” are intended to represent the existence of one or more elements. Unless otherwise specified, “a plurality of” means two or more. The expressions “comprise”, “include”, “contain” and “have” are intended as inclusive and mean that there may be other elements besides those listed. The terms such as “first” and “second” are used herein only for purposes of description and are not intended to indicate or imply relative importance and the order of formation.

Example embodiments will now be described more fully with reference to the accompanying drawings.

In embodiments described herein, there is provided a stack structure. The stack structure includes a via having a stepped side surface, which may reduce the risk of wire breakage due to the difficulty in climbing of material when the layer located above the via covers the via so as to increase the product yield. It may be appreciated that, unless stated otherwise, the term “stack” in the present disclosure may include one layer or more layers.

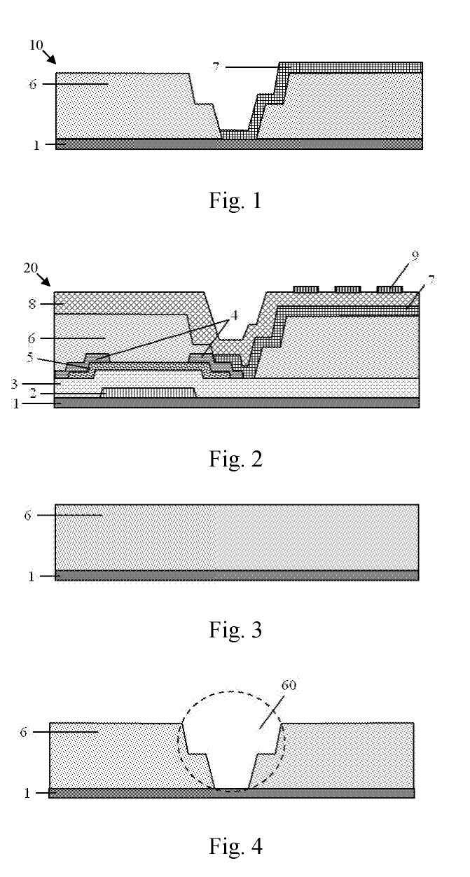

FIG. 1 is a cross-section view schematically illustrating a stack structure 10 according to an embodiment of the present disclosure. As shown in FIG. 1, the stack structure 10 includes a substrate 1, at least one material layer 6 located on the substrate 1, a via penetrating through at least one portion of the at least one material layer 6, and another material layer 7 conformally covering a side surface of the via. The substrate 1 may be a glass substrate. In this embodiment, the via has a stepped side surface, where the number of steps of the side surface of the via is greater than or equal to 1. In an exemplary embodiment, the number of steps of the side surface of the via is equal to 1.

In an exemplary embodiment, a thickness of the at least one material layer 6 is greater than a thickness of the another material layer 7. Alternatively, a ratio of the thickness of the at least one material layer 6 to the thickness of the another material layer 7 is greater than 10.

FIG. 2 is a cross-section view schematically illustrating a stack structure 20 including a thin film transistor according to an embodiment of the present disclosure. As shown in FIG. 2, the thin film transistor includes a gate electrode 2 on the substrate 1, a gate insulating layer 3 located on the substrate 1 and the gate electrode 2, an active layer 5 located on one portion of the gate insulating layer 3, and a source/drain electrode layer 4 located on the active layer 5 and the gate insulating layer 3. In this embodiment, the at least one material layer 6 covers at least the thin film transistor, the via exposes the source/drain electrode, and the another material layer 7 includes a conductive layer 7. It may be appreciated that, although the embodiments of the present disclosure are described by taking a bottom gate thin film transistor as an example, the embodiments of the present disclosure are also applicable to the case of a top gate thin film transistor. In the case of a top gate thin film transistor, the thin film transistor includes an active layer, a gate insulating layer, a gate electrode or a source/drain electrode sequentially located on the substrate, wherein the via exposes the source/drain electrode.

In an exemplary embodiment, as shown in FIG. 2, the stack structure 20 further includes a passivation layer 8 located on the conductive layer 7, and a further conductive layer 9 located on the passivation layer 8. The passivation layer 8 functions as an insulating protection, which can prevent interferences of the water vapor and impurities etc. of the external environment on the thin film transistor.

In an exemplary embodiment, the at least one material layer 6 includes an organic film layer 6. In an exemplary embodiment, a thickness of the organic film layer 6 is greater than a thickness of the conductive layer 7. Alternatively, the thickness of the organic film layer 6 is about 20,000 Angstroms, and the thickness of the conductive layer is smaller than about 1,000 Angstroms

In an exemplary embodiment, the conductive layer 7 may be a pixel electrode layer 7, and the further conductive layer 9 may be a common electrode layer 9.

In an exemplary embodiment, the organic film layer 6 includes a binder, a photoinitiator, a crosslinking monomer, etc., the pixel electrode layer 7 includes indium tin oxide, and the common electrode layer 9 includes indium tin oxide.

It may be appreciated that the pixel electrode layer 7 and the common electrode layer 9 may further include other conductive materials such as a transparent conductive oxide including indium zinc oxide or the like.

In embodiments described herein, there is further provided a method of preparing a stack structure. The prepared stack structure includes a via having a stepped side surface, which may, in case where the via has a greater depth, reduce the risk of wire breakage when a layer located above the via covers the via so as to increase the product yield.

A method of preparing a stack structure provided by the embodiments of the present disclosure will now be described in detail with reference to FIGS. 3 to 11.

FIG. 3 is a schematic diagram schematically illustrating forming at least one material layer 6 of a method of preparing a stack structure according to an embodiment of the present disclosure. As shown in FIG. 3, the at least one material layer 6 is formed on a substrate 1. The substrate 1 may be a glass substrate.

FIG. 4 is a schematic diagram schematically illustrating forming a via 60 of a method of preparing a stack structure according to an embodiment of the present disclosure. As shown in FIG. 4, the via 60 penetrating through at least one portion of the at least one material layer 6 is formed in the at least one material layer 6. In this embodiment, the via 60 has a stepped side surface. The number of steps of the side surface of the via 60 is greater than or equal to 1. In an exemplary embodiment, the number of steps of the side surface of the via 60 is equal to 1.

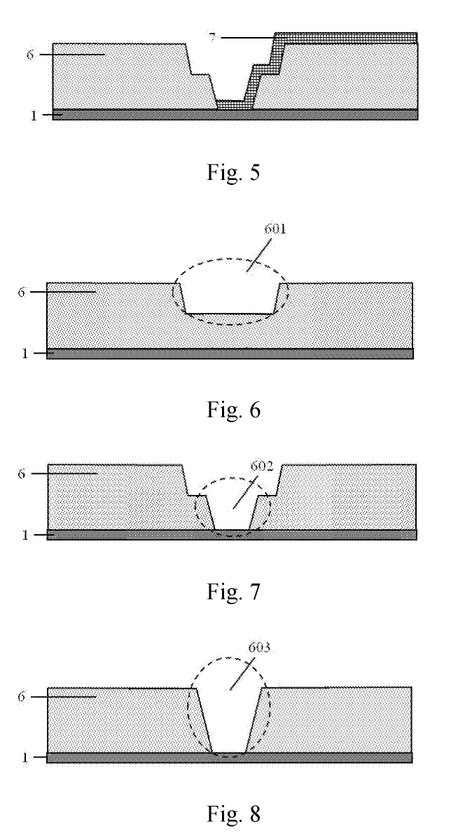

FIG. 5 is a schematic diagram schematically illustrating forming another material layer 7 of a method of preparing a stack structure according to an embodiment of the present disclosure. As shown in FIG. 5, the another material layer 7 is conformally formed on the at least one material layer 6 by a method such as deposition or sputtering etc. to cover the side surface of the via 60.

In this embodiment, a thickness of the at least one material layer 6 is greater than a thickness of the another material layer 7. Alternatively, the ratio of the thickness of the at least one material layer 6 to the thickness of the another material layer 7 is greater than 10.

Next, a method of forming the via 60 will be described with reference to FIGS. 6 to 10.

FIGS. 6 and 7 show a first method of forming the via 60. FIG. 6 is a schematic diagram schematically illustrating forming a first via 601 of a method of preparing a stack structure according to an embodiment of the present disclosure; and FIG. 7 is a schematic diagram schematically illustrating forming a second via 602 of a method of preparing a stack structure according to an embodiment of the present disclosure.

As shown in FIG. 6, firstly, the first via 601 having a first width penetrating through the at least one material layer 6 is formed by patterning. The depth of the first via 601 is smaller than the thickness of the at least one material layer 6.

As shown in FIG. 7, then, at the bottom of the first via 601, the second via 602 having a second width penetrating through the at least one material layer 6 is formed by patterning. In this embodiment, the first width is greater than the second width, and a side surface of the second via 602 is not continuous with a side surface of the first via 601. The first via 601 and the second via 602 constitute the via 60 having the stepped side surface.

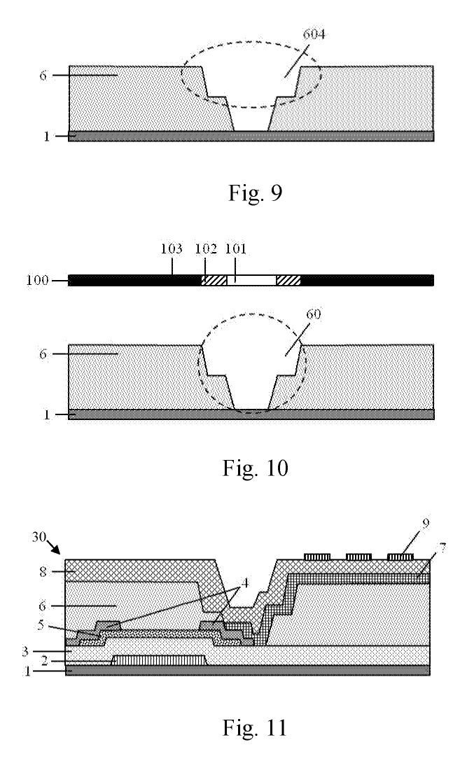

FIGS. 8 and 9 show a second method of forming the via 60.

FIG. 8 is a schematic diagram schematically illustrating forming a third via 603 of a method of preparing a stack structure according to an embodiment of the present disclosure; and FIG. 9 is a schematic diagram schematically illustrating forming a fourth via 604 of a method of preparing a stack structure according to an embodiment of the present disclosure.

As shown in FIG. 8, firstly, the third via 603 having a third width penetrating through the at least one material layer 6 is formed by patterning. In an exemplary embodiment, the third via 603 penetrates the entire at least one material layer 6.

As shown in FIG. 9, then, at the top of the third via 603, the fourth via 604 having a fourth width penetrating through the at least one material layer 6 is formed by patterning. In this embodiment, the third width is smaller than the fourth width, and a side surface of the third via 603 is not continuous with a side surface of the fourth via 604. The third via 603 and the fourth via 604 constitute the via 60 having the stepped side surface.

In an exemplary embodiment, the at least one material layer 6 includes an organic film layer 6. FIG. 10 is a schematic diagram schematically illustrating forming a via 60 in case where the at least one material layer 6 includes the organic film layer 6.

As shown in FIG. 10, the via 60 having the stepped side surface is formed in the organic film layer 6 by one patterning using a halftone mask 100. In this embodiment, the halftone mask 10 includes a fully-transparent region 101, a semi-transparent region 102 located on both sides of the fully-transparent region 101 and an opaque region 103 located on both sides of the semi-transparent region 102. During the exposure process, a region of the organic film layer 6 corresponding to the fully-transparent region 101 is fully exposed, a region of the organic film layer 6 corresponding to the semi-transparent region 102 is partially exposed, and a region of the organic film layer 6 corresponding to the opaque region 103 is not exposed. Then, the exposed portion of the organic film layer 6 is developed to form the via 60.

FIG. 11 is a schematic diagram schematically illustrating forming a stack structure 30 including a thin film transistor of a method of preparing a stack structure according to an embodiment of the present disclosure.

As shown in FIG. 11, a gate electrode 2, a gate insulating layer 3, an active layer 5, and a source/drain electrode layer 4 are sequentially formed on the substrate 1, wherein the gate electrode 2, the gate insulating layer 3, the active layer 5 and the source/drain electrode layer 4 constitute the thin film transistor, an organic film layer 6 is formed on the thin film transistor, a via penetrating through the organic film layer 6 is formed in the organic film layer 6 by one patterning, wherein the via has a step-shaped side surface and the via exposes the source/drain electrode, another material layer 7 is conformally formed on the organic film layer 6, wherein the another material layer 7 includes a conductive layer 7, a passivation layer 8 is conformally formed on the conductive layer 7, and a further conductive layer 9 is formed on the passivation layer 8. It may be appreciated that, although the embodiments of the present disclosure are described by taking a bottom gate thin film transistor as an example, the embodiments of the present disclosure are also applicable to the case of a top gate thin film transistor. In the case of a top gate thin film transistor, the thin film transistor includes an active layer, a gate insulating layer, a gate electrode or a source/drain electrode sequentially located on the substrate, wherein the via exposes the gate electrode or the source/drain electrode.

In an exemplary embodiment, a thickness of the organic film layer 6 is greater than a thickness of the conductive layer 7. Alternatively, the thickness of the organic film layer 6 is about 20,000 Angstroms, and the thickness of the conductive layer is smaller than about 1,000 Angstroms

In an exemplary embodiment, the conductive layer 7 includes a pixel electrode layer 7, and the further conductive layer 9 includes a common electrode layer.

In an exemplary embodiment, the organic film layer 6 includes a binder, a photoinitiator, a crosslinking monomer, etc., the pixel electrode layer 7 includes indium tin oxide, and the common electrode layer 9 includes indium tin oxide.

It may be appreciated that the pixel electrode layer 7 and the common electrode layer 9 further include other conductive materials such as a transparent conductive oxide including indium zinc oxide or the like.

In embodiments described herein, there is provided a stack structure and a preparation method thereof. The stack structure includes a via having a stepped side surface, which may reduce the risk of wire breakage due to the difficulty in climbing of material when the layer located above the via covers the via so as to increase the product yield.

The foregoing description of the embodiments has been provided for purpose of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are included within the scope of the disclosure.

1. A stack structure comprising:
a substrate;
at least one material layer located on the substrate;
a via penetrating through at least one portion of the at least one material layer, wherein the via has a stepped side surface; and
another material layer conformally covering the stepped side surface of the via.

2. The stack structure according to claim 1, wherein a ratio of a thickness of the at least one material layer to a thickness of the another material layer is greater than 10.

3. The stack structure according to claim 2, wherein the stack structure further comprises a thin film transistor, wherein the at least one material layer covers at least the thin film transistor, wherein the via exposes one of a source/drain electrode and a gate electrode of the thin film transistor, and wherein the another material layer comprises a conductive layer.

4. The stack structure according to claim 3, wherein the at least one material layer comprises an organic film layer.

5. The stack structure according to claim 4, wherein a thickness of the organic film layer is about 20,000 Angstroms, and wherein a thickness of the conductive layer is smaller than about 1,000 Angstroms.

6. The stack structure according to claim 4, further comprising:
a passivation layer located on the conductive layer; and
a further conductive layer located on the passivation layer.

7. A method of preparing a stack structure, the method comprising:
forming at least one material layer on a substrate;
forming a via penetrating through at least one portion of the at least one material layer in the at least one material layer, wherein the via has a stepped side surface; and
conformally forming another material layer on the at least one material layer to cover the stepped side surface of the via.

8. The method according to claim 7, wherein a ratio of a thickness of the at least one material layer to a thickness of the another material layer is greater than 10.

9. The method according to claim 7, wherein forming the via comprises:
forming a first via having a first width penetrating through the at least one material layer, wherein a depth of the first via is smaller than a thickness of the at least one material layer; and
forming, at the bottom of the first via, a second via having a second width penetrating through the at least one material layer, wherein the first width is greater than the second width, and wherein a side surface of the second via is not continuous with a side surface of the first via.

10. The method according to claim 7, wherein forming the via comprises:
forming a third via having a third width penetrating through the at least one material layer; and
forming, at the top of the third via, a fourth via having a fourth width penetrating through the at least one material layer, wherein the third width is smaller than the fourth width, and wherein a side surface of the third via is not continuous with a side surface of the fourth via.

11. The method according to claim 7, wherein the at least one material layer comprises an organic film layer.

12. The method according to claim 11, wherein forming the via comprises:
forming the via having the stepped side surface by one patterning process using a halftone mask, wherein the halftone mask comprises a fully-transparent region, a semi-transparent region located on both sides of the fully-transparent region and an opaque region located on both sides of the semi-transparent region.

13. The method according to claim 11, wherein the method further comprises:
forming a thin film transistor on the substrate prior to forming the at least one material layer, wherein the via exposes one of a source/drain electrode and a gate electrode of the thin film transistor, and wherein the another material layer comprises a conductive layer;
forming a passivation layer on the another material layer; and
forming a further conductive layer on the passivation layer.

14. A method of preparing a stack structure according to claim 13, wherein a thickness of the organic film layer is about 20,000 Angstroms, and wherein a thickness of the conductive layer is smaller than about 1,000 Angstroms.

15. The stack structure according to claim 1, wherein the stack structure further comprises a thin film transistor, wherein the at least one material layer covers at least the thin film transistor, wherein the via exposes one of a source/drain electrode and a gate electrode of the thin film transistor, and wherein the another material layer comprises a conductive layer.

16. The stack structure according to claim 1, wherein the at least one material layer comprises an organic film layer.

17. The stack structure according to claim 2, wherein the at least one material layer comprises an organic film layer.

18. The stack structure according to claim 3, further comprising:
a passivation layer located on the conductive layer; and
a further conductive layer located on the passivation layer.

19. The method according to claim 8, wherein forming the via comprises:
forming a first via having a first width penetrating through the at least one material layer, wherein a depth of the first via is smaller than a thickness of the at least one material layer; and
forming, at the bottom of the first via, a second via having a second width penetrating through the at least one material layer, wherein the first width is greater than the second width, and wherein a side surface of the second via is not continuous with a side surface of the first via.

20. The method according to claim 8, wherein a forming the via comprises:
forming a third via having a third width penetrating through the at least one material layer; and
forming, at the top of the third via, a fourth via having a fourth width penetrating through the at least one material layer, wherein the third width is smaller than the fourth width, and wherein a side surface of the third via is not continuous with a side surface of the fourth via.
